(19) United States
(12) Patent Application Publication
(10) Pub. No.: US 2014/0137934 A1
(43) Pub. Date: May 22, 2014

(54) PHOTOVOLTAIC CELL AND METHOD OF MANUFACTURING SUCH A CELL

(71) Applicant: Lambert Johan Geerligs, Petten (NL)

(72) Inventor: Lambert Johan Geerligs, Petten (NL)

(73) Assignee: STICHTING ENERGIEONDERZOEK CENTRUM NEDERLAND, Petten (NL)

(21) Appl. No.: 14/126,585

(22) PCT Filed: Jun. 15, 2012
(86) PCT No.: PCT/NL2012/050420

§ 371 Date: Feb. 5, 2014

(30) Foreign Application Priority Data
Jun. 17, 2011 (NL) 20006956

(51) Int. Cl. H01L 31/0224

(52) U.S. Cl. CPC H01L 31/022425
USPC 136/256; 438/98

(57) ABSTRACT

A fire through conductor paste is applied as a plurality of mutually separate islands on a dielectric layer on a semi-conductor body of a photo-voltaic cell. A connecting structure of a further conductor paste is applied connecting the islands, at least on the dielectric layer between locations of the islands, so that the islands are connected by the connecting structure. Different compositions are used for the fire through conductor paste and the further conductor paste, which behave differently during firing. The fire through conductor paste and the further conductor paste are fired under process conditions wherein the fire through conductor paste fires through the dielectric layer and the further conductor paste does not fire through the dielectric layer. In this way the fire through metal paste establishes electric contact through the dielectric layer between the semi-conductor body and a structure formed from the further conductor paste.

### FIELD OF THE INVENTION

The invention relates to a photovoltaic cell and a method of manufacturing a photovoltaic cell.

### BACKGROUND

A photovoltaic cell such as a solar cell, comprises a semi-conductor body with electrodes on its surface, in electric contact with the semi-conductor body.

U.S. Pat. No. 5,279,682 discloses a solar cell with a bus bar removed from intimate contact with the semi-conductor body. The cell has fingers in low resistance electrical contact with the semiconductor substrate and a bus bar of conductive material disposed at right angles to the fingers and in low resistance electrical contact with the front surfaces of each of the fingers. The fingers are made of a paste or viscous ink designed to make intimate contact with the underlying semiconductor substrate. The bus bar is formed of a selected paste or viscous ink or an epoxy composition containing particles of a conductive metal applied to the front surface of the anti-reflective coating at right angles to and contacting the fingers. In this configuration, only a small fraction of each finger is covered by the bus bar or solder pad in order to provide for electrical contact while covering a minimum of cell area with the bus bar.

Apart from their nominal function of conducting a current of photovoltaically excited free charge carriers from the body, the electrodes like the fingers that are in contact with the semi-conductor have the known negative effect that they give rise to increased recombination of charge carriers at the interface between the electrodes and the semi-conductor body, which detracts from the current and voltage.

It is known to minimize this effect by limiting the electrical contact area between the semi-conductor body and the electrodes. Experiments to reduce recombination are described in an article by Giovanna Laudisio et al, titled “Improved c-si cell performance through metallizations adapted to reduce recombination effects”, published at the 24th European Photovoltaic Solar Energy Conference, 21-25 Sep. 2009, Hamburg, Germany, pages 1446-1448. Laudisio et al. use an electrode structure with a main conductor (the busbar) and fingers that extend from the busbar.

It is known to apply such an electrode structure by printing a metal containing paste onto an electrically insulating dielectric layer on the semi-conductor body, followed by a firing step (heating) in which material from the paste penetrates the dielectric layer to make electrical contact with the semi-conductor body. Pastes for this purpose are commercially available. In one example, such a paste contains grains containing a metal such as silver or aluminium, solvent and glass frit. In the firing step the glass frit melts. The corrosive effect of the molten class causes it to etch through the dielectric layer and the nearby surface of the semi-conductor body. Furthermore the molten glass helps sinter the metal grains and establish electrical and mechanical contact to the semi-conductor body.

Laudisio et al. propose to print the electrode structure in two steps:

a first step to print the fingers, as in the known process, and a second step to print the busbar using a paste with a different composition designed so that it will not penetrate through the dielectric layer during the firing step. This can be realized for example by using a reduced amount of glass frit in the paste, and/or by adding modifiers that reduce the etching effect of the glass frit. After these two printing steps, Laudisio et al. performed a firing step. As a result of the use of the difference between the pastes, contact between the electrode structure and the semi-conductor body, and the associated surface recombination of charge carriers is limited to the fingers. The busbar is not in direct contact with the semi-conductor body and thus does not contribute to recombination. The efficiency loss due to recombination is limited to the fingers.

U.S. Pat. No. 5,178,685 discloses a method of forming solar cell contacts wherein two different silver inks are applied to form solder pads and elongated contact fingers providing Ohmic contact to the semi-conductor body respectively. A firing step is executed when both inks have been applied that makes silver ink from the contact finger pass through a silicon nitride layer on the substrate to form the contacts and that bonds the silver particles from the ink of the solder pads to the substrate. Ends of the fingers underlie the solder pads to form an electrical connection between the fingers and the solder pads. Here too the solder pads cover only a small fraction of each finger.

### SUMMARY

Among others, it is an object to provide for a photo-voltaic cell and a method of manufacturing such a cell wherein recombination is reduced.

A method of manufacturing a photo-voltaic cell is provided that comprises

applying a fire through conductor paste as a plurality of mutually separate islands on a dielectric layer on a semi-conductor body of the photo-voltaic cell;

applying a connecting structure of a further conductor paste for connecting the islands, the further conductor paste being applied at least on the dielectric layer between locations of the islands and in a position to contact a major part of the surface of each island and/or its boundary;

firing the fire through conductor paste and the further conductor paste, under process conditions wherein the fire through conductor paste fires through the dielectric layer and the further conductor paste does not fire through the dielectric layer, whereby the fire through metal paste establishes electric contact through the dielectric layer between the semi-conductor body and a structure formed from the further conductor paste.

Because the fire through conductor paste provides for contact to the semi-conductor body only locally, contact to the semi-conductor body and resulting recombination loss is reduced. At the same time the connecting structure connects the islands. A major part, i.e. at least half, of the island's surface and/or perimeter connects to the connecting structure. The connecting structure may be applied after application of the islands, or before, for example when only the perimeter of the islands is in contact with the connecting structure. Preferably as much as possible of the islands is connected, with the entire top surface and/or perimeter in contact with the connecting structure.

The firing step of the fire through conductor paste may result in sintering of conductive grains in that paste, accompanied by etching through the dielectric layer, for example due to contact with molten glass frit from the fire through metal paste. The firing step of the further conductor paste, which may be the same firing step as for the fire through conductor paste, may result in sintering conductive grains in the further conductor paste, but without etching, or at least without complete through etching of the dielectric layer. The fire through conductor paste and the further conductor paste may be metal pastes for example, i.e. pastes with grains of a metal such as silver. Preferably, the fire through conductor paste and the further conductor paste have mutually different compositions, so that they fire through and not respectively, under similar process conditions. But if separate firing steps with different process conditions are used, it may be possible to use similar compositions.

In an embodiment the connecting structure is applied over at least part of the fire through conductor paste of the plurality of islands and on the dielectric layer between the islands. Alternatively, the connecting structure may be in contact only with the perimeter of the islands, in which case the step of applying the paste of the connecting structure could be executed before the step of applying the fire through conductor paste.

In an embodiment the connecting structure is comprises a linear structure successively connecting a series of the islands. A straight linear structure or a linear structural with bends may be used. Due to the use of a linear structure a connection is provided that covers only a small amount of the surface area of the is to be covered by the connecting structure.

In an embodiment the fire through conductor paste and the further conductor paste are fired together in a common firing step, the further conductor paste being a non-fire through conductor paste under the process conditions of the common firing step. This simplifies the manufacturing process. In one example, a difference between the compositions of the pastes may provide for firing through and non-firing through under the process conditions. Relatively different amounts of glass frit in the pastes may be used to produce this effect, and/or different amounts of added modifiers. The paste with the highest etching speed may be applied in the islands the paste with the lowest etching speed, or no etching effect at all, may be applied in the overlying structure. The duration of the firing step may selected higher than the time needed by the paste of the islands to etch through dielectric layer and below the time needed by the paste in the overlying structure to etch through dielectric layer.

The fire through conductor paste and the structure may be applied on the front of the photo-voltaic cell, i.e. the surface that allows most light to pass to the semi-conductor body. In an embodiment the fire through conductor paste is applied on the dielectric layer in a succession of mutually separate islands, the further conductor paste running in the structure successively over the islands in the succession. The further conductor paste may be used to form an electrode finger that leaves adjacent areas open for passing light to the semi-conductor body.

In an embodiment the structure has edges along a length direction of the structure, the fire through metal paste lying confined to an area between the edges. This realizes finger conductivity with a minimal loss due to recombination.

According to an aspect a photo-voltaic cell is provided that comprises

a semi-conductor body of the photo-voltaic cell;

a dielectric layer on the semiconductor body;

a fired conductor structure over the dielectric layer, locally isolated from the semi-conductor body by the dielectric layer;

mutually separate islands of a fired conductor penetrating through the dielectric layer to the semi-conductor body, between the fired conductor structure and the semi-conductor body, the fired conductor structure connecting the islands.

Use of islands of fire through conductor, typically sintered conductors, reduces recombination loss.

### BRIEF DESCRIPTION OF THE DRAWING

These and other objects and advantageous aspects will become apparent from a description of exemplary embodiments, using the following figures.

FIG. 1 shows a plane view of the top surface of a photovoltaic cell

FIG. 2 shows a schematic cross section through a finger

FIG. 3 shows a flow-chart of a process of manufacturing a photovoltaic cell

FIGS. 4-7 illustrate stages during manufacturing a photovoltaic cell

### DETAILED DESCRIPTION OF EXEMPLARY EMBODIMENTS

FIG. 1 shows a plane view of the top surface of a photovoltaic cell comprising an electrode structure 10 of electrically conductive material on top of a semi-conductor body 12. By way of example an electrode structure with fingers 14 and a busbar 16 is shown. Fingers 14 extend from busbar 16 along a length direction of fingers 14 indicated by arrow A.

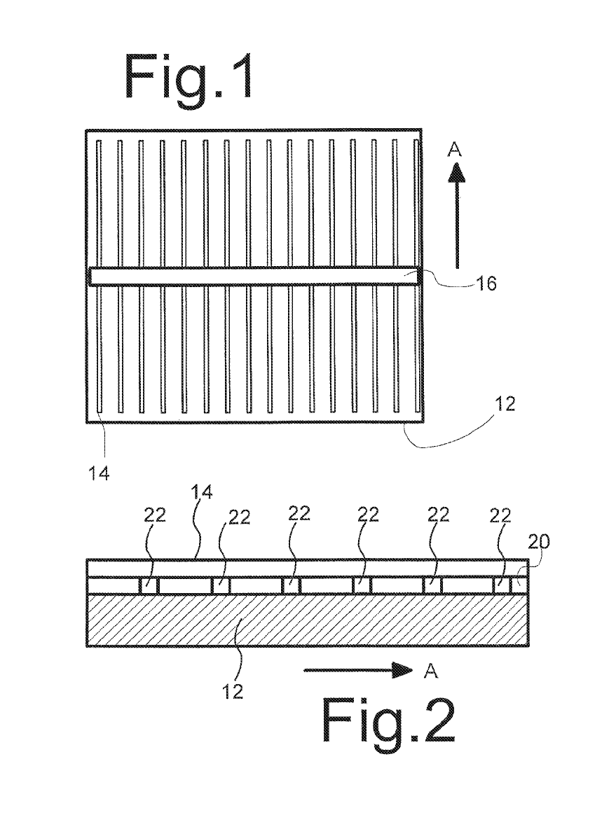

FIG. 2 shows a schematic cross section through a finger 14 along this direction. On top of semi-conductor body 12 a dielectric layer 20 is provided. Between finger 14 and semi-conductor body 12 a plurality of contacts 22 is provided through dielectric layer 20. Contacts 22 are made of fire through material, i.e. typically of sintered conductor grains.

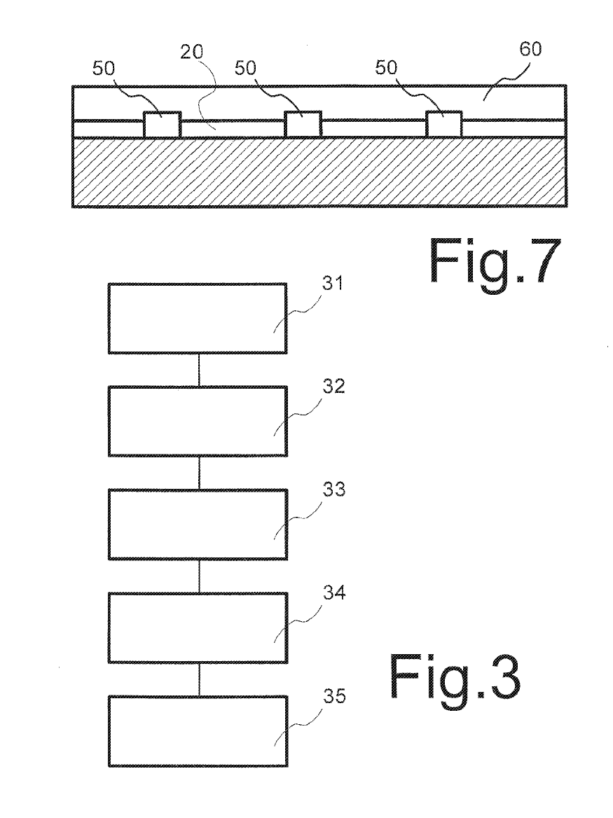

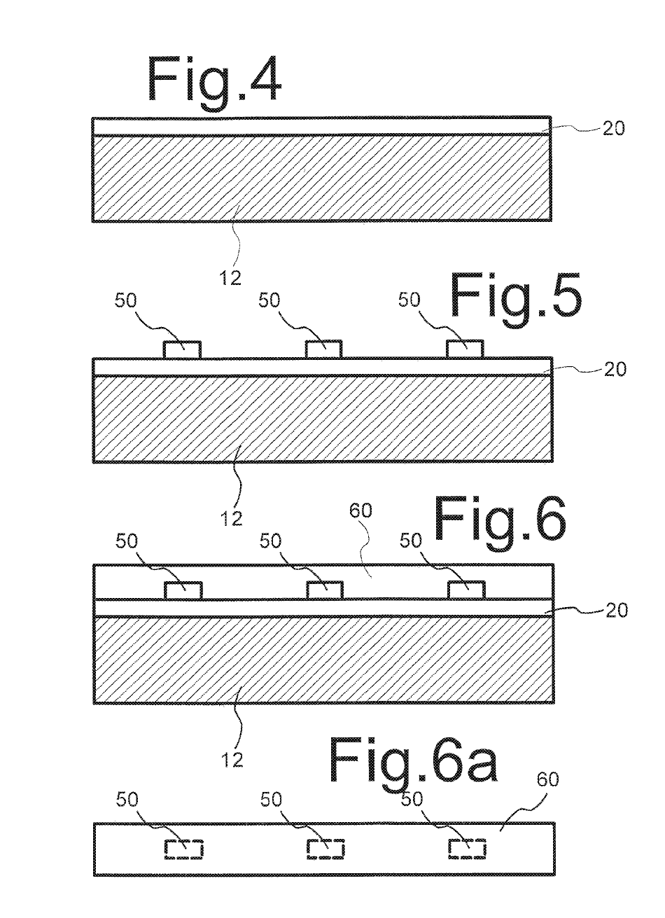

FIG. 3 shows a flow-chart of a process of manufacturing a photovoltaic cell. After a number of conventional preparatory steps, symbolized by first step 31, this process provides for an intermediate product comprising a semi-conductor body with a dielectric layer on top, but as yet without electrode structure. FIG. 4 shows a cross-section of the intermediate product at the top, comprising semi-conductor body 12 with a continuous dielectric layer 20. Continuous dielectric layer 20 may be an anti-reflection coating for example or another passivating coating. Although for the sake of simplicity semi-conductor body 12 is shown to have a flat surface, it should be appreciated that it may have a textured surface, for example with pyramid shaped protrusions. Although for the sake of simplicity a single dielectric layer 20 is shown, it should be appreciated that the dielectric layer could be made up of a stack of multiple layers of different dielectric materials, or that the dielectric layer may comprise of a material with a variable composition as a function of height.

In a second step 32, a firing through paste is printed on dielectric layer 20 in a printing pattern that defines rows of mutually separate islands. Fire through pastes are known per se, for example from an article by S. Arimoto et al, titled “Simplified mass-production process for 16% efficiency multi-crystalline si solar cells”, published in the Conference Record of the Twenty-Eighth IEEE Photovoltaic Specialists Conference, 2000, page 188-193. Fire through pastes are also known from an article titled “Thick-Film Metallization for Solar Cell Applications” by Gary C. Cheek et al, published in the IEEE TRANSACTIONS ON ELECTRON DEVICES, VOL. ED-31, NO. 5, MAY 1984 pages 602-609.

A paste of conductor grains (e.g. metal grains) may be used with added solvent that makes the paste printable and etching agent such as glass frit, to etch through dielectric layer 20, in one example silver grains, combined with glass forming metal oxides and an organic solvent may be used. FIG. 5 shows a cross-section of the result, with a row of printed islands 50 of fire through paste on dielectric layer 20. Islands 50 may have a length of typically 100-500 μm in the direction of the length of the finger and typically 50-150 μm in the direction of the width of the finger for example. The height of the islands may be typically 5-40 μm.

In a third step 33, a non-firing through paste is printed in a printing pattern that defines lines, each line extending over a row of the islands. Non-fire through paste is also known as “low activity paste” or “floating busbar paste”. A low activity paste is commercially available from the company Heraeus (http://pvsilverpaste.com) under the product name SOL315. US20100243048 discloses a non-fire through paste. One known way of providing fire through pastes and non-fire through pastes is to exploit the fact that silver does not react with SiNx and Si At temperatures below 840C. Added glass powder in a paste with silver grains, typically a lead-borosilicate glass, may be used to etch through the SiNx layer and establish mechanical contact to the silicon. Therefore, silver pastes with and without added glas powder may be used as fire through and non-fire through paste respectively, when the temperature in the firing step is kept below 840C. Binder and solvents may be used in the paste to optimize the paste. A common binder and solvent is ethyl cellulose and terpineol. Non-fire through pastes are known for example from the article by Laudisio et al. A non-fire through paste may comprise metal grains and solvent e.g. grains of silver (Ag) in an organic solvent but without etching agent that is effective for dielectric layer 20, or at least insufficient etching agent to penetrate dielectric layer 20 during firing.

FIG. 6 shows a cross-section of the result of printing, with printed islands 50 of fire through paste on dielectric layer 20 and a printed line 60 of non fire through paste over the islands 50 and on dielectric layer 20 where islands 50 are absent. FIG. 6a shown a top view, with printed line 60. The circumference of islands 50 below printed line 60 is indicated schematically by dashed contours (for the sake of simplicity rectangular contours are shown, but in practice different shapes, e.g. more rounded shapes, may be used). Printed line may have a width of typically 50-200 μm for example, and a height of typically 5-40 μm.

In a fourth step 34, the semi-conductor body 12 with dielectric layer 20, printed islands 50 and printed line 60 is subjected to firing, that is, it is heated to a temperature at which the metal particles in the pastes are sintered. Sintering results in a conductive body of electrically connected particles (possibly a porous body). In the case of the fire through paste, heating results in local opening of dielectric layer 20 so that sintered grains make electrical contact to the semi-conductor body. In the case of the non-fire through paste, heating merely results in a mechanical connection between the grains and dielectric layer 20 FIG. 7 shows a cross-section of the result. Firing results in the formation of finger 14 from printed line 60. As a result of firing material from the islands has penetrated dielectric layer 20 to contact semi-conductor body 12, which results in an electric connection between finger 14 and semi-conductor body 12. Although not shown in the figure, it should be appreciated that the material in the islands typically is a porous body of sintered grains, which have fused at their contact points, leaving inter grain spaces elsewhere.

It is not necessary that the non-firing through paste printed in third step 33 has no etching effect at all. As should be appreciated, it may suffice that there is a difference in the compositions of the pastes used for printing in second step 32 and third step 33 that affects the ratio between their etching speeds through dielectric layer 20 during firing. In one example, a relative difference between the amount of glass frit in the pastes has this effect, and/or the amounts of added modifiers. The paste with the highest etching speed is printed in second step 22 and the paste with the lowest etching speed, or no etching effect at all, is printed in third step 23. The duration of the subsequent firing step 34 is selected higher than the time needed by the paste of second step 22 to etch through dielectric layer 20 and below the time needed by the paste of third step 23 to etch through dielectric layer 20. By selecting suitable paste compositions and paste combinations, and process conditions such as firing profiles, it is possible to realize conductive metallization that makes mechanical contact to the photo-voltaic cell but differs in its electrical contacting properties and its impact on recombination in the semiconductor body 12, for example as a result of the difference in the amount of etching.

Subsequent to fourth step 34, conventional steps may be performed to finish the photo-voltaic cell. These steps are symbolized by a fifth step 35. Together, first step 31 and fifth step 35 may provide for the creation of an emitter in semi-conductor body 12, for example by diffusion or by forming semi-conductor body 12 by adding an emitter layer to a semi-conductor substrate, surface fields, further electrodes, other dielectric layers etc.

In the resulting photo-voltaic cell the area of actual contact between semi-conductor body 12 and fire through material is smaller than the area of fingers 14, because contacts are provided only in separate islands below a finger 14. Thus, charge carrier loss due to recombination at the electrode structure is reduced, compared to fingers that make contact over their entire area. As the area reduction narrows the current path only over a small part of the current path (over the height of the islands) output impedance of the photovoltaic cell is hardly affected. The process of manufacturing does not require an additional firing step, compared to a process that only provides for fingers and no islands, because the fingers and the islands are fired both in the same step. Alternatively, islands 50 may be fired before lines 60 are printed and fired. In this case an additional firing step is needed.

Although an embodiment has been described wherein the non-firing through paste is printed in linear structures in the form of straight lines it should be appreciated that alternatively the linear structure could run along a bent line connecting a series of islands or it could connect the islands in a non-sequential way, e.g. in a tree structure of lines or with a printed area under which islands are located in parallel and not only in a linear succession.

Although an embodiment has been shown wherein lines 60 are wider than islands 50, so that lines 60 extend beyond islands in all directions, it should be appreciated that alternatively the islands 50 may extend up to an edge of line 60 or even beyond. Islands 50 that do not extend beyond the edges of lines 60, i.e. islands that are entirely covered by the connecting structure formed by lines 60, have the advantage that recombination is minimized. A greater diameter will not have a significant effect on output impedance. Preferably, at least half the surface area of each islands is covered by the connecting structure formed by lines 60 and preferably the entire surface is covered. When the entire surface is covered, e.g. because edges of lines 60 lie beyond the end of islands 50, this has the advantage that the resistivity of lines 60 is maximally reduced without affecting recombination.

In another embodiment, instead of a plurality of islands a stripe of fire through material may be used that extends continuously along the length of finger 14, the stripe being narrower than line 60. In this way recombination is reduces compared to using fired through fingers only. However, the use of mutually separate islands 50 under the same finger 14 has the advantage that the same reduction of contact area with semi-conductor body 12 can be realized with wider structures, which are easier to print.

Although an embodiment has been described wherein the non-firing through paste is applied after the firing through paste, it should be appreciated that alternatively the order of the printing may be partly reversed, for example by first printing non-firing through paste in regions connecting locations of the islands with (e.g. printing the linear structure 60 in an interrupted fashion), followed by printing of the islands with firing through paste, filling the gaps in linear structure 60. In this case, the top surface of the islands is left uncovered by the linear structure 60. In this embodiment the connecting structure 60 preferably contacts at least half of the perimeter of each island, and preferably the entire perimeter. In this way, conductivity dependence on resistivity within the islands is reduced.

In an alternative process, the electrical connection between semi-conductor body 12 and fingers 14 may be realized by creating openings in dielectric layer 20, for example by laser ablation or etching in the presence of a sacrificial mask on the surface of dielectric layer 20, the mask leaving dielectric layer 20 selectively exposed at the location of the openings, and depositing conductive material in the openings. However, the use of a fire through paste, which can be applied by printing, reduces the complexity and costs of the process.

1. A method of manufacturing a photo-voltaic cell comprising
applying a fire through conductor paste as a plurality of mutually separate islands on a dielectric layer on a semi-conductor body of the photo-voltaic cell;
applying a connecting structure of a further conductor paste for connecting the islands, the further conductor paste being applied at least on the dielectric layer between locations of the islands and in a position to contact a major part of the surface of each island and/or its perimeter;
firing the fire through conductor paste and the further conductor paste, under process conditions wherein the fire through conductor paste fires through the dielectric layer and the further conductor paste does not fire through the dielectric layer, whereby the fire through conductor paste establishes electric contact through the dielectric layer between the semi-conductor body and a structure formed from the further conductor paste.

2. A method according to claim 1, wherein the connecting structure is applied over at least part of the fire through conductor paste of the plurality of islands and on the dielectric layer between the islands.

3. A method according to claim 1, wherein the connecting structure comprises a linear structure successively connecting a series of the islands.

4. A method according to claim 1, wherein the fire through conductor paste and the further conductor paste are fired together in a common firing step, the further conductor paste being a non-fire through paste at least under the process conditions of the common firing step.

5. A method according to claim 1, wherein the fire through conductor paste is applied on the dielectric layer in a succession of mutually separate islands, the connecting structure running successively over the islands in the succession.

6. A method according to claim 1, wherein the connecting structure has edges along a length direction of the connecting structure defining edges of an area of the dielectric layer that is covered by the connecting structure, the fire through conductor paste lying confined to the area between the edges.

7. A method according to claim 1, wherein the fire through conductor paste and the connecting structure are applied on a main light collection side of the photo-voltaic cell.

8. A method according to claim 1, wherein the connecting structure covers at least half a top surface of each of the islands, and/or contacts at least half a perimeter of each island.

9. A photo-voltaic cell, comprising
a semi-conductor body of the photo-voltaic cell;
a dielectric layer on the semiconductor body;
mutually separate islands of a fired conductor penetrating through the dielectric layer to the semi-conductor body
a connecting sintered conductor structure over the dielectric layer and in electric contact with the islands, locally electrically isolated from the semi-conductor body by the dielectric layer and connected to the semi-conductor body via the islands, the connecting conductor structure electrically connecting the islands.

10. A photo-voltaic cell according to claim 9, wherein the connecting structure runs over the islands, the islands lying between the connecting conductor structure and the semi-conductor body.

11. A photo-voltaic cell according to claim 9, wherein the islands of the fired conductor and the connecting sintered conductor structure comprise sintered conductor grains.

12. A photo-voltaic cell according to claim 9, wherein the connecting structure has edges along a length direction of the connecting structure, defining edges of an area of the dielectric layer that is covered by the connecting structure, the islands lying confined to the area between the edges.
